(19) United States
(12) Patent Application Publication
(10) Pub. No.: US 2010/0171218 A1
(43) Pub. Date: Jul. 8, 2010

(54) SEMICONDUCTOR DEVICE AND METHOD FOR FABRICATING THE SAME

(75) Inventor: Nobuo AOI, Hyogo (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/724,090

(22) Filed: Mar. 15, 2010

Related U.S. Application Data
(63) Continuation of application No. PCT/JP2009/003164, filed on Jul. 7, 2009.

(30) Foreign Application Priority Data
Sep. 26, 2008 (JP) 2008-248680

(51) Int. Cl. H01L 23/48; H01L 21/768

(52) U.S. Cl. 257/741; 438/667; 257/774; 438/618; 257/E21.597; 257/E23.011

(57) ABSTRACT

A semiconductor device includes a first substrate formed with a through silicon via reaching the back surface thereof, and a second substrate electrically connected to the first substrate via the through silicon via, and bonded to the back surface of the first substrate. A taper angle of a sidewall of a tip end portion of the through silicon via connected to the second substrate is larger than a taper angle of a sidewall of the other portion thereof.

### CROSS-REFERENCE TO RELATED APPLICATION

This is a continuation of PCT International Application PCT/JP2009/003164 filed on Jul. 7, 2009, which claims priority to Japanese Patent Application No. 2008-248680 filed on Sep. 26, 2008. The disclosures of these applications including the specifications, the drawings, and the claims are hereby incorporated by reference in its entirety.

### BACKGROUND

The present disclosure relates to a semiconductor device and a method for fabricating the same, and particularly to a structure of through silicon vias which provides a wafer-to-wafer, chip-to-wafer, or chip-to-chip connection in a semiconductor device having a three-dimensional integrated circuit.

In recent years, a three-dimensional integrated circuit element has been developed in which a plurality of chips electrically connected to each other by through silicon vias are stacked. Such a three-dimensional integrated circuit element is typically fabricated as follows.

First, a plurality of transistors are formed on a principal surface of a silicon substrate. Next, after an interlayer insulating film and a contact are formed, a hole for forming through silicon vias is formed, and copper which forms a through silicon via covered with a dielectric liner and a barrier metal layer onto it is buried therein. Then, an interconnect layer is further formed on the interlayer insulating film. Then, chemical mechanical polishing (CMP) is performed on the back surface of the silicon substrate to planarize the back surface of the substrate. Thereafter, the back surface of the silicon substrate is further etched and removed by a dry etching process so that the bottom portion of the hole for forming a through silicon via, i.e., the bottom portion of the through silicon via is exposed. In this manner, the back-surface electrode terminal of one chip is formed. Subsequently, the bottom-surface of through silicon via of the one chip is thermocompressed to the top-surface of electrode of another chip formed separately, thereby providing a connection (a wafer-to-wafer, chip-to-wafer, or chip-to-chip connection) between the individual substrates via the through silicon via (see, e.g., ITRS 2007 Assembly & Package Chapter, pp. 35-37).

FIG. 6 is a cross-sectional view showing a conventional through silicon via formed in a silicon substrate (prior to the polishing of the back surface of the substrate). As shown in FIG. 6, over a silicon substrate 101 formed with gate electrode structures 102, there is formed an interlayer insulating film 103A. In the interlayer insulating film 103A, there is formed a contact 107 reaching the silicon substrate 101. A barrier metal film 106A is formed so as to cover the wall surface of a hole for forming a through silicon via which is formed in the silicon substrate 101 and the interlayer insulating film 103A, and a copper film 106B is formed on the barrier metal film 106A so as to be buried in the hole for forming a through silicon via, whereby a through silicon via 106 is formed. On the interlayer insulating film 103A, there is formed an interlayer insulating film 103B. In the interlayer insulating film 103B, there is formed a multilayer interconnect 104 connected to the through silicon via 106 and the contact 107. In a surface portion of the interlayer insulating film 103B, there is formed an electrode terminal 105 connected to the multilevel interconnect 104. In this manner, a chip 100 having the through silicon via 106 (or the chip 100 formed in a wafer before dicing, which shall hold true hereinafter) is formed.

As can be seen from FIG. 6, the bottom surface of the conventional through silicon via typically has a flat shape.

In the case where the bottom portion (exposed portion) of such a through silicon via is connected as the electrode of one chip to the electrode of the other chip, when the electrodes of the two chips are each made of copper, a high temperature and a high pressure are required for the connection of the electrodes of the two chips. Accordingly, a method for connecting the electrodes of the two chips at a low temperature under a small strength of compression has been reported which changes the electrode as the exposed portion of the through silicon via to an alloy, also changes the electrode of the other chip fabricated separately to an alloy, and connects the electrodes changed to the alloys (see, e.g., 3D System Integration by Chip-to-Wafer Stacking Technologies, Peter Ramm et al., Extended Abstracts of the 2003 International Conference on Solid State Devices and Materials, pp. 376-377).

### SUMMARY

However, a three-dimensional integrated circuit element in which a plurality of chips electrically connected to each other by the conventional through silicon via described above are stacked has the problem of poor reliability of a chip-to-chip electrical connection.

The three-dimensional integrated circuit element also has a problem that, when the electrodes are to be connected at a low temperature under a small strength of compression, an additional step of changing each of the electrodes to an alloy is necessary to result in the problems of a complicated process and increased cost.

In view of the foregoing, an object of the present invention is to enable, in a three-dimensional integrated circuit element in which a plurality of chips electrically connected to each other by a through silicon via are stacked, the provision of a reliable electrical connection between the chips via the through silicon via.

To attain the object, the present inventor has studied the cause of the poor reliability of the chip-to-chip electrical connection in the three-dimensional integrated circuit element in which the plurality of chips electrically connected to each other by the conventional through silicon via are stacked, and made the following findings.

FIG. 7 is a cross-sectional view of a semiconductor device in which the plurality of chips electrically connected to each other by the conventional through silicon via are stacked. Note that, since the chip 100 shown in FIG. 7 has basically the same structure as that of the chip 100 shown in FIG. 6, a repeated description thereof is omitted. As shown in FIG. 7, over a silicon substrate 201 formed with gate electrode structures 202, there is formed an interlayer insulating film 203. In the interlayer insulating film 203, there are formed contacts 207 reaching the silicon substrate 201. In the interlayer insulating film 203, there is also formed a multilayer interconnect 204 connected to the contacts 207, while in a surface portion of the interlayer insulating film 203, there are formed electrodes 205 connected to the multilayer interconnect 204. In this manner, a chip 200 (or the chip 200 formed in a wafer before dicing, which shall hold true hereinafter) is formed. The chip 200 is bonded to the back surface of the chip 100.

However, as described above, electrical connections may not be able to be provided between the electrodes of the chip 100 formed of the exposed portions of the through silicon vias 106 and the electrodes 205 of the chip 200. The reason for this is as follows.

As shown in FIG. 7, a step of exposing the through silicon vias 106 (i.e., copper buried in the holes for forming through silicon vias) using a dry etching process on the back-surface side of the chip 100, i.e., the silicon substrate 101 is controlled by an etching period so that the heights of the exposed portions of the through silicon vias 106 vary over the surface of the substrate (or over the surface of a wafer when the formation of the through silicon vias is performed on a wafer level, which shall hold true hereinafter). Note that the variations result from variations in the size of a resist pattern in a lithographic step for forming the holes for forming through silicon vias and from etching speed variations over the surface of the substrate in the dry etching step for forming the holes for forming through silicon vias or exposing the through silicon vias 106.

In addition, as shown in FIG. 7, thickness variations and bowing occur in the silicon substrates 101 and 201 each in a wafer state. Therefore, it is impossible to hold the back surface of the silicon substrate 101 provided with the electrodes formed of the exposed portions of the through silicon vias 106 in parallel with the top surface of the silicon substrate 201 provided with the electrodes 205. Consequently, the distances between the bottom surfaces of the electrodes formed of the exposed portions of the through silicon vias 106 and the upper surfaces of the electrodes 205 have variations. As a result, when the electrodes of the two chips are thermocompressed to each other, the applied pressure varies over the surfaces of the substrates. In the worst case, a gap is formed between the opposing electrodes of the two chips to prevent the provision of a connection between the electrodes of the two chips.

Based on the foregoing findings, the present inventor has conceived the invention in which the exposed portion (tip end portion connected to the other chip) of the through silicon via serving as the electrode terminal is formed into a tapered shape, unlike the shape of the other portion thereof, to allow easy deformation of the exposed portions. As a result, even when there are variations in the distances between the electrodes of the two chips, the exposed portion of the through silicon via having a relatively short distance between the electrodes of the two chips can be deformed when the electrodes are thermocompressed to each other, and the influence of the variations in the distances between the electrodes can be eliminated.

Specifically, a semiconductor device according to the present disclosure includes: a first substrate formed with a through silicon via reaching the back surface thereof; and a second substrate electrically connected to the first substrate via the through silicon via, and bonded to the back surface of the first substrate, wherein a taper angle of a sidewall of a tip end portion of the through silicon via connected to the second substrate is larger than a taper angle of a sidewall of the other portion thereof.

Here, the taper angle of the sidewall of the through silicon via indicates an angle with respect to a direction in which the through silicon via extends, i.e., a direction perpendicular to a principal surface of the substrate.

In the semiconductor device according to the present disclosure, the tip end portion of the through silicon via may have a conical shape or a pyramidal shape.

In the semiconductor device according to the present disclosure, the through silicon via may contain copper as a main component thereof.

In the semiconductor device according to the present disclosure, each of the first substrate and the second substrate may be a silicon substrate.

In the semiconductor device according to the present disclosure, an end portion of the through silicon via opposite to the tip end portion may be connected to an interconnect formed on the first substrate.

In the semiconductor device according to the present disclosure, the tip end portion of the through silicon via may be connected to an electrode terminal formed on the second substrate.

A method for fabricating a semiconductor device according to the present disclosure includes the steps of: (a) forming a hole for forming a through silicon via in a first substrate; (b) etching a portion of the first substrate located under the hole for forming a through silicon via to adjust a taper angle of a wall surface of a bottom portion of the hole for forming a through silicon via to be larger than a taper angle of a wall surface of the other portion thereof; (c) after the step (b), burying a conductive material in the hole for forming a through silicon via to form a through silicon via; (d) after the step (c), thinning the first substrate from the back surface thereof so as to expose at least a portion of the through silicon via formed in the bottom portion of the hole for forming a through silicon via; and (e) after the step (d), bonding a second substrate to the back surface of the first substrate, and electrically connecting the exposed portion of the through silicon via to an electrode terminal formed on the second substrate.

Here, the taper angle of the wall surface of the hole for forming a through silicon via indicates an angle with respect to a direction in which the hole for forming a through silicon via extends, i.e., a direction perpendicular to a principal surface of the substrate.

In the method for fabricating a semiconductor device according to the present disclosure, the step (d) may include the step of polishing the back surface of the first substrate so as not to expose the through silicon via, and then etching the back surface of the first substrate so as to expose at least the portion of the through silicon via formed in the bottom portion of the hole for forming a through silicon via.

In the method for fabricating a semiconductor device according to the present disclosure, the step (e) may include the step of electrically connecting the exposed portion of the through silicon via and the electrode terminal by thermocompression.

In the method for fabricating a semiconductor device according to the present disclosure, in the step (b), the portion of the first substrate located under the hole for forming a through silicon via may be etched using a wet etching process.

In this case, the first substrate may be a silicon substrate having a (100) crystal plane as a principal surface thereof, and the wall surface of the bottom portion of the hole for forming a through silicon via after the step (b) is performed may be a (111) crystal plane.

In the method for fabricating a semiconductor device according to the present disclosure, in the step (b), the portion of the first substrate located under the hole for forming a through silicon via may be etched using a dry etching process.

According to the present disclosure, the taper angle of the sidewall of the tip end portion of the through silicon via connected to the second substrate (i.e., the other chip) is larger than the taper angle of the sidewall of the other portion thereof. In other words, the tip end portion of the through silicon via is formed into a tapered shape, unlike the shape of the other portion thereof. As a result, the electrode terminal obtained by exposing the tip end portion can be easily deformed. Therefore, even when there are variations in the distance (distance between the electrodes) between the electrode terminal and the electrode terminal of the other chip, the exposed portion of the through silicon via having a relatively short distance between the electrodes is deformed when the electrodes of the two chips are thermocompressed to each other. This eliminates the influence of the variations in the distance between the electrodes, and allows the avoidance of a situation where a gap is formed between the opposing electrodes of the two chips, and an electrical connection cannot be obtained therebetween. That is, an electrical connection can be reliably obtained between the chips via the through silicon via.

In addition, according to the present disclosure, the electrode terminal obtained by exposing the tip end portion of the through silicon via can be easily deformed. As a result, the electrode terminal and the electrode terminal of the other chip can be reliably connected at a low temperature under a small weight. Since the electrodes of the two chips can be connected at a low temperature under a small weight without being changed into alloys even when the electrodes of the two chips are each made of copper which is a low-resistance material, it is possible to provide an electrical connection having a low resistance and high reliability between the chips, while preventing a complicated process, i.e., increased cost.

As described above, the semiconductor device and the method for fabricating the same according to the present disclosure allows an electrical connection to be reliably provided between the chips via the through silicon via, and are particularly useful when a wafer-to-wafer, chip-to-wafer, or chip-to-chip connection is provided in a semiconductor device having a three-dimensional integrated circuit.

### BRIEF DESCRIPTION OF THE DRAWINGS

FIG. 1 is a cross-sectional view showing a through silicon via according to the present disclosure that is formed in a substrate (prior to the polishing of the back surface of the substrate).

FIGS. 2A-2H are cross-sectional views showing the individual steps of a method for fabricating a semiconductor device according to an embodiment of the present disclosure.

FIGS. 3A-3D are cross-sectional views showing the individual steps of the method for fabricating the semiconductor device according to the embodiment of the present disclosure.

FIG. 4 is a cross-sectional view showing an example of the semiconductor device according to the embodiment of the present disclosure.

FIGS. 5A and 5B are views each showing the electrode terminal of one chip formed of an exposed portion of a through silicon via and the electrode terminal of the other chip which are connected by thermocompression in the method for fabricating the semiconductor device according to the embodiment of the present disclosure.

FIG. 6 is a cross-sectional view showing a conventional through silicon via formed in a silicon substrate (prior to the polishing of the back surface of a substrate).

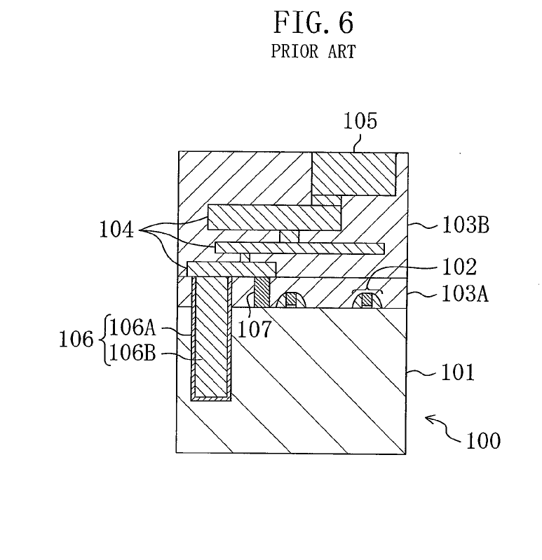

FIG. 7 is a cross-sectional view of a semiconductor device in which a plurality of chips electrically connected to each other by the conventional through silicon via are stacked.

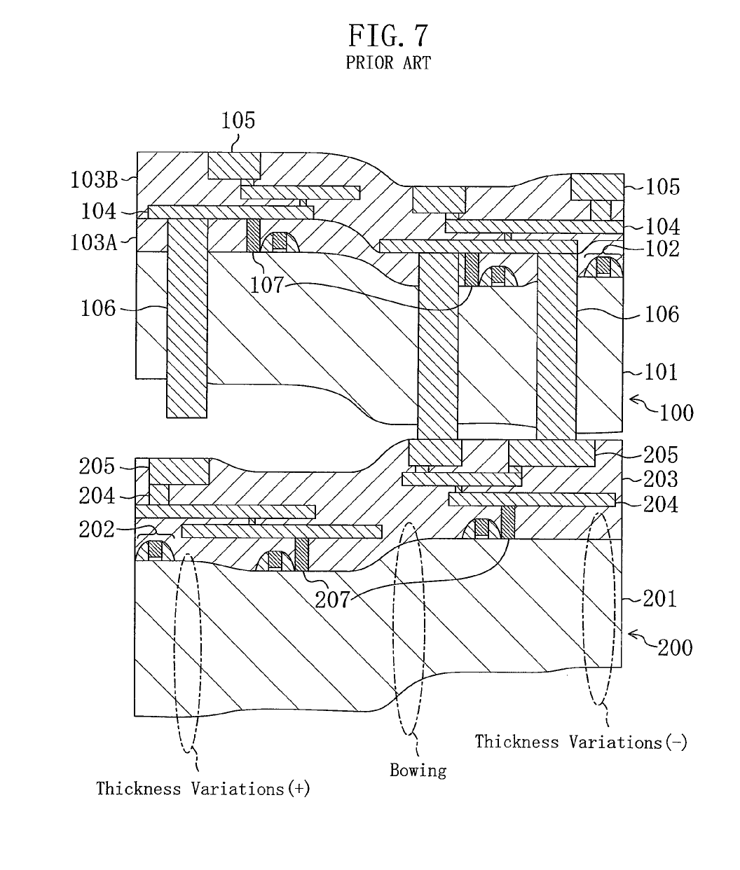

### DETAILED DESCRIPTION

### Embodiments

Referring to the drawings, a semiconductor device and a method for fabricating the same according to an embodiment of the present disclosure will be described below.

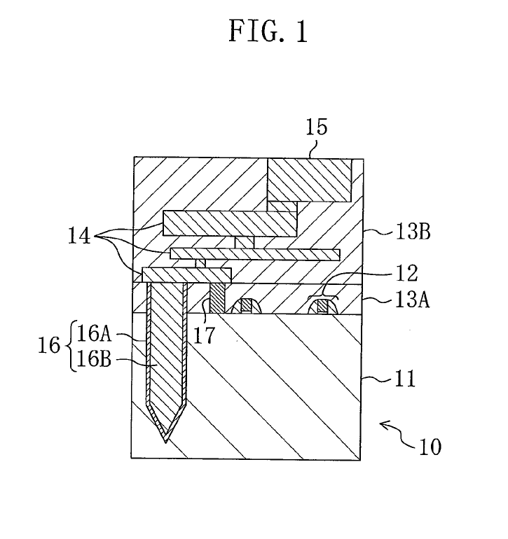

FIG. 1 is a cross-sectional view showing a through silicon via according to the present disclosure that is formed in a substrate (prior to the polishing of the back surface of the substrate). As shown in FIG. 1, over a silicon substrate 11 formed with gate electrode structures 12, there is formed an interlayer insulating film 13A. In the interlayer insulating film 13A, there is formed a contact 17 reaching the silicon substrate 11. A barrier metal film 16A is formed so as to cover the wall surface of a hole for forming a through silicon via which is formed in the silicon substrate 11 and the interlayer insulating film 13A, and a copper film 16B is formed on the barrier metal film 16A so as to be buried in the hole for forming a through silicon via, thereby forming a through silicon via 16. On the interlayer insulating film 13A, there is formed an interlayer insulating film 13B. In the interlayer insulating film 13B, there is formed a multilayer interconnect 14 connected to an upper portion of each of the through silicon via 16 and the contact 17 and, in a surface portion of the interlayer insulating film 13B, there is formed an electrode terminal 15 connected to the multilayer interconnect 14. In this manner, a chip 10 having the through silicon via 16 (or the chip 10 formed in a wafer before dicing, which shall hold true hereinafter) is formed.

As can be seen from FIG. 1, the through silicon via 16 (or the hole for forming a through silicon via) according to the present embodiment is characterized in that the bottom portion thereof has a tapered cross-sectional shape. In other words, the sidewall of the bottom portion of the through silicon via 16 is largely tapered from a direction in which the through silicon via 16 extends, compared with the sidewall of the other portion thereof.

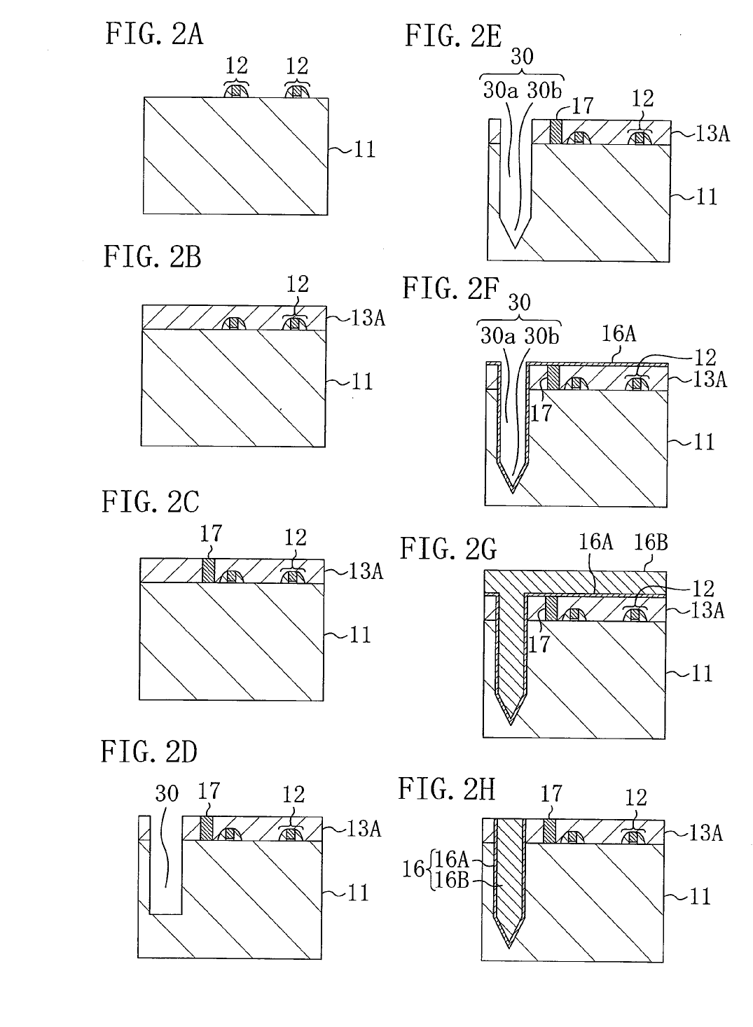

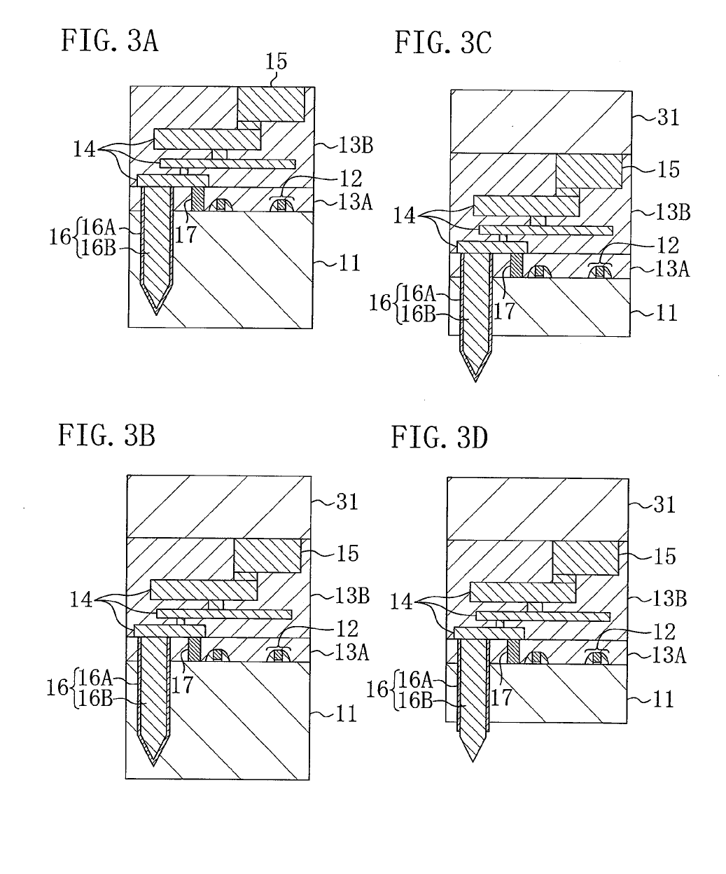

FIGS. 2A-2H and 3A-3D are cross-sectional views showing the individual steps of the method for fabricating the semiconductor device according to the present embodiment.

First, as shown in FIG. 2A, the gate electrode structures 12 of the plurality of transistors are formed on the silicon substrate 11. Next, as shown in FIG. 2B, the interlayer insulating film (first interlayer insulating film) 13A formed of, e.g., a chemical vapor deposition (CVD) oxide film is deposited over the silicon substrate 11 so as to cover the gate electrode structures 12. Then, the surface of the interlayer insulating film 13A is planarized by CMP. Next, as shown in FIG. 2C, a contact hole is formed in a predetermined region of the interlayer insulating film 13A using a lithographic technique and a dry etching technique. Then, in the contact hole, tungsten, e.g., is buried to form the contact 17.

Next, as shown in FIG. 2D, a hole 30 for forming a through silicon via extending through the interlayer insulating film 13A, and reaching a depth of, e.g., 30 μm in the silicon substrate 11 is formed using, e.g., a dry etching process. The diameter of the hole 30 for forming a through silicon via is, e.g., 5 μm. The formation of the hole 30 for forming a through silicon via is performed by controlling the period of the etching.

Next, as shown in FIG. 2E, etching is performed on the portion of the silicon substrate 11 located under the hole 30 for forming a through silicon via using, e.g., a wet etching process so as to process the bottom portion of the hole 30 for forming a through silicon via into a tapered shape (e.g., a conical shape or a pyramidal shape). That is, the wall surface of the bottom portion 30b of the hole 30 for forming a through silicon via is largely tapered from the direction in which the hole 30 for forming a through silicon via extends, compared with the other portion 30a thereof. Here, as the silicon substrate 11, a silicon substrate having a (100) crystal plane as a principal surface thereof is used and, as an etchant, a 25 wt % tetramethyl ammonium hydroxide solution, e.g., is used. By dipping the silicon substrate 11 in a wafer state formed with the hole 30 for forming a through silicon via in the etchant at 90° C. for 10 minutes, etching is performed. As a result, an etching speed in the (100) crystal plane becomes about 300 to 400 times an etching speed in a (111) crystal plane so that the wall surface of the bottom portion 30b of the hole 30 for forming a through silicon via becomes the (111) crystal plane. When the diameter of the hole 30 for forming a through silicon via is assumed to be 5 μm, the depth of the bottom portion 30b of the hole 30 for forming a through silicon via having the tapered shape is about not less than 5 μm.

Next, as shown in FIG. 2F, a CVD oxide film (not shown) having a thickness of 200 nm e.g., is formed so as to cover the inner wall surface of the hole 30 for forming a through silicon via. Subsequently, as the barrier metal film 16A, a titanium nitride film having a thickness of 50 nm and a titanium film having a thickness of 50 nm are successively formed by a sputtering process so as to cover the inner wall surface of the hole 30 for forming a through silicon via.

Next, as shown in FIG. 2G, the copper film 16B is formed by, e.g., an electrolytic plating process so as to be buried in the hole 30 for forming a through silicon via. Then, as shown in FIG. 2H, the copper film 16B and the barrier metal film 16A formed on the interlayer insulating film 13A are removed by, e.g., CMP such that they are left only in the hole 30 for forming a through silicon via. In this manner, the through silicon via 16 having the bottom portion in a tapered shape such as, e.g., a conical shape or a pyramidal shape is formed.

Next, as shown in FIG. 3A, using a typical method for forming a buried interconnect, the interlayer insulating film (laminated insulating film) 13B is formed on the interlayer insulating film 13A, and the multilayer interconnect 14 connected to the through silicon via 16 and the contact 17 is formed in the interlayer insulating film 13B. Then, the electrode terminal 15 connected to the multilayer interconnect 14 is formed in the surface portion of the interlayer insulating film 13B.

Next, as shown in FIG. 3B, the uppermost surface of the interlayer insulating film 13B (the upper surface of the uppermost interconnect layer) is bonded to a support substrate 31.

Next, as shown in FIG. 3C, polishing is performed on the back surface of the silicon substrate 11 to reduce the thickness thereof so as not to expose the through silicon via 16. Then, dry etching is performed on the entire back surface of the silicon substrate 11 so as to completely expose at least the portion of the through silicon via 16 (i.e., the bottom portion of the through silicon via 16 having the tapered shape) formed in the bottom portion 30b (see FIG. 2E) of the hole 30 for forming a through silicon via.

Next, as shown in FIG. 3D, the CVD oxide film (not shown) and the barrier metal film 16A each covering the exposed portion of the through silicon via 16 are removed by, e.g., dry etching to expose the copper film 16B forming the exposed portion. In this manner, one chip having the through silicon via 16 is formed. Then, another chip fabricated separately is bonded to the back surface of the chip, and the electrode terminal formed of the exposed portion of the through silicon via 16 and an electrode terminal formed on the other chip are electrically connected by, e.g., thermocompression. Thereafter, the support substrate 31 is stripped from the resulting chip stack.

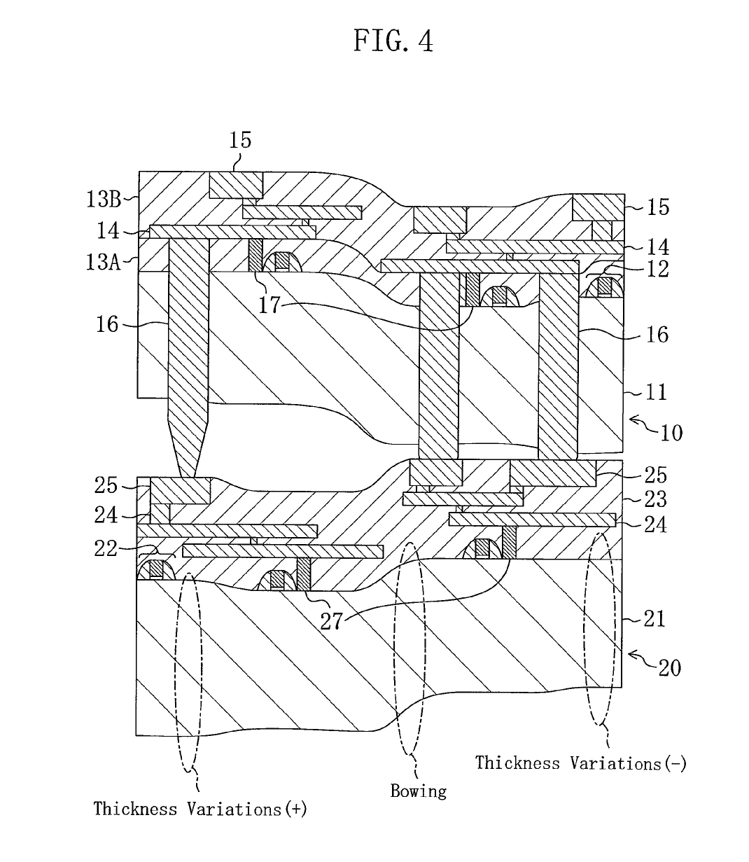

FIG. 4 is a cross-sectional view showing an example of the semiconductor device according to the present embodiment formed by the steps described above. Since the chip 10 shown in FIG. 4 has basically the same structure as that of the chip 10 shown in FIG. 1, a repeated description thereof is omitted. As shown in FIG. 4, over a silicon substrate 21 formed with gate electrode structures 22, there is formed an interlayer insulating film 23. In the interlayer insulating film 23, there are formed contacts 27 reaching the silicon substrate 21. In the interlayer insulating film 23, there is also formed a multilayer interconnect 24 connected to the contacts 27 and, in a surface portion of the interlayer insulating film 23, there are formed electrodes 25 connected to the multilayer interconnect 24. The electrodes 25 are each formed of, e.g., a copper film. In this manner, a chip 20 (or the chip 20 formed in a wafer before dicing, which shall hold true hereinafter) is formed. The chip 20 is bonded to the back surface of the chip 10 with, e.g., an adhesive layer (not shown) interposed therebetween.

According to the present embodiment, the taper angle of the sidewall of the exposed portion (tip end portion) of each of the through silicon vias 16 forming the electrodes of the chip 10 is larger than the taper angle of the sidewall of the other portion thereof. In other words, the tip end portion of the through silicon via 16 is formed into a tapered shape, unlike the shape of the other portion thereof. As a result, the electrode terminal obtained by exposing the tip end portion can be easily deformed. Therefore, even when there are variations in the distance (distance between the electrodes) between the electrode terminal and the corresponding electrode terminal 25 of the other chip 20, the exposed portion of the through silicon via 16 having a relatively short distance between the electrodes is deformed when the electrodes of the chips 10 and 20 are thermocompressed to each other. This eliminates the influence of the variations in the distance between the electrodes, and allows the avoidance of a situation where a gap is formed between the opposing electrodes of the two chips, and an electrical connection cannot be obtained therebetween. That is, an electrical connection is reliably provided between each of the electrodes of the chip 10 formed of the exposed portion of the through silicon via 16 and the corresponding electrode terminal 25 of the chip 20, and therefore an electrical connection can be reliably provided between the chips via the through silicon via 16.

In the present embodiment, the bonding of the chips 10 and 20 may be performed in such a manner that each of the chips 10 and 20 is in a wafer state (wafer-to-wafer connection) or in a chip state after dicing (chip-to-chip connection). Alternatively, the bonding of the chips 10 and 20 may also be performed in such a manner that one of the chips 10 and 20 is in a wafer state, and the other thereof is in a chip state (chip-to-wafer connection).

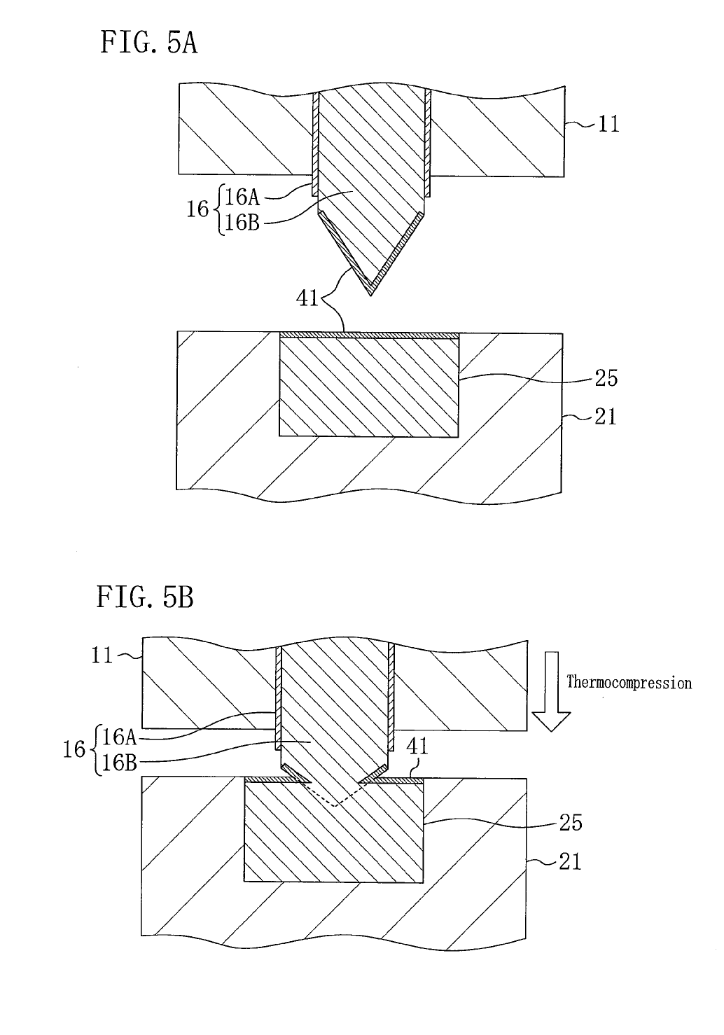

FIGS. 5A and 5B show the electrode terminal of the chip 10 formed of the exposed portion of the through silicon via 16 and the electrode terminal 25 of the chip 20 which are connected by thermocompression.

As shown in FIG. 5A, if the bottom portion of the through silicon via 16 as the exposed portion is processed into a tapered shape, when the electrode terminal formed of that portion is thermocompressed to the electrode terminal 25 of the chip 20 fabricated separately as shown in FIG. 5B, the bottom portion of the through silicon via 16 having the tapered shape bites into the electrode terminal 25. At the time when the thermocompression is started, a natural oxide film 41 is formed on each of the respective surfaces of the copper film 16B forming the bottom portion of the through silicon via 16 and the electrode terminal 25. However, since the copper film 16B forming the bottom portion of the through silicon via 16 is easily deformed by the thermocompression, it becomes possible to provide a connection between the bottom portion of the through silicon via 16 and the electrode terminal 25, while removing the natural oxide film 41. That is, the electrodes of the two chips can be connected at a low temperature under a small weight without being changed into alloys. Therefore, it is possible to provide a chip-to-chip electrical connection having a low resistance and high reliability, while preventing a complicated process, i.e., increased cost.

In the present embodiment, the hole 30 for forming a through silicon via shown in FIG. 2D is formed by controlling the period of dry etching. However, in this case also, variations occur in the height of the bottom surface of the formed hole 30 for forming a through silicon via so that variations consequently occur in the height of the bottom portion (exposed portion) of the through silicon via 16 serving as the electrode terminal. In addition, because thickness variations and bowing have occurred in the silicon substrates 11 and 21, it is impossible to hold the back surface of the silicon substrate 11 provided with the electrodes formed of the exposed portions of the through silicon vias 16 in parallel with the top surface of the silicon substrate 21 provided with the electrodes 25. As a result, variations occur in the distance (distance between the electrodes) between the bottom surface of each of the electrodes formed of the exposed portions of the through silicon vias 16 and the upper surface of the corresponding electrode terminal 25. However, as described above, the bottom portion (exposed portion) of each of the through silicon vias 16 serving as the electrodes has a tapered shape, and is easily deformed when the electrodes of the two chips are thermocompressed to each other. Therefore, it is possible to eliminate the influence of the variations in the distance between the electrodes, and prevent the occurrence of connection failure between the electrodes.

In the present embodiment, copper (Cu) is used as a main component of the through silicon via 16, but a copper alloy such as CuAl may also be used instead of copper (Cu). In this case, a copper alloy may also be used only in the bottom portion of the through silicon via 16 and the side portion thereof. By thus using a copper alloy instead of copper, it is possible to reduce a temperature when the bottom portion of the through silicon via 16 and the electrode terminal 25 are thermocompressed to each other.

In the present embodiment, the silicon (Si) substrate is used as the substrate, but it will be appreciated that, even when another substrate such as a SiGe substrate is used, the same effects are obtainable.

In the present embodiment, etching is performed on the portion of the silicon substrate 11 located under the hole 30 for forming a through silicon via using the wet etching process in the step shown in FIG. 2E to process the bottom portion 30b of the hole 30 for forming a through silicon via into the tapered shape. However, it is also possible to use a dry etching process instead of the wet etching process. Specifically, in the step of forming the hole 30 for forming a through silicon via shown in FIG. 2D, processing is performed under selected etching conditions under which the wall surface of the hole 30 for forming a through silicon via becomes vertical. Then, in the step shown in FIG. 2E, the etching conditions are changed to those under which a deposit is attached to the wall surface of the hole 30 for forming a through silicon via to allow processing such that the bottom portion 30b of the hole 30 for forming a through silicon via is formed with a tapered wall surface, i.e., the bottom portion 30b has the tapered shape.

What is claimed is:

1. A semiconductor device, comprising:
a first substrate formed with a through silicon via reaching the back surface thereof; and
a second substrate electrically connected to the first substrate via the through silicon via, and bonded to the back surface of the first substrate,
wherein a taper angle of a sidewall of a tip end portion of the through silicon via connected to the second substrate is larger than a taper angle of a sidewall of the other portion thereof.

2. The semiconductor device of claim 1, wherein the tip end portion of the through silicon via has a conical shape or a pyramidal shape.

3. The semiconductor device of claim 1, wherein the through silicon via contains copper as a main component thereof.

4. The semiconductor device of claim 1, wherein each of the first substrate and the second substrate is a silicon substrate.

5. The semiconductor device of claim 1, wherein an end portion of the through silicon via opposite to the tip end portion is connected to an interconnect formed on the first substrate.

6. The semiconductor device of claim 1, wherein the tip end portion of the through silicon via is connected to an electrode terminal formed on the second substrate.

7. A method for fabricating a semiconductor device, comprising the steps of:
(a) forming a hole for forming a through silicon via in a first substrate;
(b) etching a portion of the first substrate located under the hole for forming a through silicon via to adjust a taper angle of a wall surface of a bottom portion of the hole for forming a through silicon via to be larger than a taper angle of a wall surface of the other portion thereof;
(c) after the step (b), burying a conductive material in the hole for forming a through silicon via to form a through silicon via;
(d) after the step (c), thinning the first substrate from the back surface thereof so as to expose at least a portion of the through silicon via formed in the bottom portion of the hole for forming a through silicon via; and
(e) after the step (d), bonding a second substrate to the back surface of the first substrate, and electrically connecting the exposed portion of the through silicon via to an electrode terminal formed on the second substrate.

8. The method of claim 7, wherein the step (d) includes the step of polishing the back surface of the first substrate so as not to expose the through silicon via, and then etching the back surface of the first substrate so as to expose at least the portion of the through silicon via formed in the bottom portion of the hole for forming a through silicon via.

9. The method of claim 7, wherein the step (e) includes the step of electrically connecting the exposed portion of the through silicon via and the electrode terminal by thermocompression.

10. The method of claim 7, wherein, in the step (b), the portion of the first substrate located under the hole for forming a through silicon via is etched using a wet etching process.

11. The method of claim 10, wherein
the first substrate is a silicon substrate having a (100) crystal plane as a principal surface thereof, and
the wall surface of the bottom portion of the hole for forming a through silicon via after the step (b) is performed is a (111) crystal plane.

12. The method of claim 7, wherein, in the step (b), the portion of the first substrate located under the hole for forming a through silicon via is etched using a dry etching process.
